(19) United States
(12) Patent Application Publication
(10) Pub. No.: US 2019/0385500 A1
(43) Pub. Date: Dec. 19, 2019

(54) DETECTION DEVICE AND METHOD FOR ARRAY SUBSTRATE ROW DRIVE CIRCUIT

(71) Applicant: WUHAN CHINA STAR OPTOELECTRONICS TECHNOLOGY CO., LTD., Wuhan, Hubei (CN)

(72) Inventor: Tianhua Gao, Wuhan, Hubei (CN)

(73) Assignee: WUHAN CHINA STAR OPTOELECTRONICS TECHNOLOGY CO., LTD, Wuhan, Hubei (CN)

(21) Appl. No.: 15/519,347

(22) PCT Filed: Feb. 28, 2017
(86) PCT No.: PCT/CN2017/075084

§ 371 Date: May 14, 2019

(30) Foreign Application Priority Data
Feb. 13, 2017 (CN) 201710075519.X

(51) Int. Cl. G09G 3/20; G01R 31/40

(52) U.S. Cl. CPC G09G 3/20; G01R 31/40

(57) ABSTRACT

Disclosed is a detection device and method for an array substrate row drive circuit. The detection device includes: an input module for inputting a test signal to a first-stage row drive unit of the row drive circuit; an acquisition module for acquiring an output signal of each row drive unit; and a detection module for determining an abnormally active row drive unit based on output signals of all row drive units when it is judged that the row drive circuit is operating abnormally. The abnormally active row drive unit can be determined.

### CROSS-REFERENCE TO RELATED APPLICATIONS

The present application claims the priority of Chinese patent application CN 201710075519.X, entitled “Detection device and method for array substrate row drive circuit” and filed on Feb. 13, 2017, the entirety of which is incorporated herein by reference.

### FIELD OF THE INVENTION

The present disclosure relates to the field of detection technologies for display panels, and particularly, to a detection device and method for an array substrate row drive circuit.

### BACKGROUND OF THE INVENTION

In recent years, low-temperature polysilicon (LTPS) technology is widely used in high-end mobile phones and tablet products. The LTPS technology has become one of the most important technologies in a developing procedure of high pixels per inch (PPI, the number of pixels per inch) products because of its advantages such as low power consumption, high reaction rate, and high aperture ratio. In order to improve production efficiency and production yield, it is essential to monitor and test a manufacturing procedure of LTPS products and semi-finished products.

At present, a check mechanism in a manufacturing procedure of LTPS products mainly includes electrical testing, optical detection, and so on. Electrical testing comprises array substrate detection, which includes main test items of an LTPS product array substrate row drive circuit, a gate line, a data line, etc.

The defect of a detection device of the array substrate row drive circuit in the prior art lies in that the detection device can only reflect abnormality of the array substrate row drive circuit as a whole, but cannot further determine a row drive unit in which the abnormality is generated, thereby increasing difficulty in parsing the abnormality.

### SUMMARY OF THE INVENTION

In order to solve the above-mentioned technical problem, the present disclosure provides a detection device and method for an array substrate row drive circuit.

According to one aspect of the present disclosure, a detection device for an array substrate row drive circuit is provided, comprising:

an input module for inputting a test signal to a first-stage row drive unit of the row drive circuit, the row drive circuit including a plurality of cascaded row drive units;

an acquisition module for acquiring an output signal of each row drive unit; and

a detection module for determining an abnormally active row drive unit based on output signals of all row drive units when it is judged that the row drive circuit is operating abnormally.

In one embodiment, the detection module comprises:

a plurality of conversion units, wherein each of the conversion units corresponds to a stage of row drive unit for converting an output signal of the stage of row drive unit into a pulse signal and preventing the pulse signal from overlapping a pulse signal corresponding to any other row drive unit;

a superimposition unit for superimposing pulse signals output from all the conversion units, to obtain a superimposed signal; and

a determination unit for determining an abnormally active row drive unit based on the superimposed signal.

In one embodiment, the conversion unit includes an NAND circuit, for performing an NAND operation on a clock signal and the output signal of a row drive unit corresponding to the conversion unit, to obtain the pulse signal.

In one embodiment, the determination unit is specifically used for determining a missing waveform in the superimposed signal and determining a row drive unit corresponding to the missing waveform as the abnormally active row drive unit.

In one embodiment, the detection device further comprises a display module for displaying a waveform of the superimposed signal.

In one embodiment, the detection module further comprises:

a judgment unit for determining, based on an output signal of a last-stage row drive unit, an operating state of the row drive circuit.

According to another aspect of the present disclosure, a detection method for an array substrate row drive circuit is provided, comprising the steps of:

inputting a test signal to a first-stage row drive unit of the row drive circuit, the row drive circuit including a plurality of cascaded row drive units;

acquiring an output signal of each row drive unit; and

determining an abnormally active row drive unit based on output signals of all row drive units when it is judged that the row drive circuit is operating abnormally.

In one embodiment, the step of determining an abnormally active row drive unit based on the output signals of all the row drive units comprises:

converting, with respect to each of the row drive units, an output signal of the row drive unit into a pulse signal, and preventing the pulse signal from overlapping a pulse signal corresponding to any other row drive unit;

superimposing pulse signals output from all the conversion units, to obtain a superimposed signal; and

determining an abnormally active row drive unit based on the superimposed signal.

In one embodiment, converting, with respect to each of the row drive units, an output signal of the row drive unit into a pulse signal, and preventing the pulse signal from overlapping a pulse signal corresponding to any other row drive unit comprises:

performing, with respect to each of the row drive units, an NAND operation on a clock signal and the output signal corresponding to the row drive unit, to obtain the pulse signal.

In one embodiment, determining an abnormally active row drive unit based on the superimposed signal comprises:

determining a missing waveform in the superimposed signal, and determining a row drive unit corresponding to the missing waveform as the abnormally active row drive unit.

In one embodiment, the above detection method further comprises displaying a waveform of the superimposed signal.

In one embodiment, determining an abnormally active row drive unit comprises: determining, based on an output signal of a last-stage row drive unit, an operating state of the row drive circuit, which may be in a normal or an abnormal operating state.

One or more embodiments of the present disclosure may have the following advantages over the prior art.

With the detection device for the array substrate row drive circuit of the present disclosure, the abnormally active row drive unit can be determined based on the acquired output signals of all the row drive units when the row drive circuit is in abnormal operation. As compared with an existing solution in which it is possible to reflect the operating state of the row drive circuit as a whole only in accordance with the acquired output signal of the last-stage row drive unit, in the solution of the present disclosure, with the knowledge of abnormality of the row drive circuit as a whole, the position of the abnormally active row drive unit can be further determined, thereby improving the efficiency in detecting and parsing the abnormally active row drive unit. It can be seen that in the present disclosure, a more specific detection result can be obtained, thereby facilitating subsequent repair of the row drive circuit, and remarkably shortening the time for defect investigation in and elimination from the row drive circuit.

Other features and advantages of the present disclosure will be further explained in the following description, and partly become self-evident therefrom, or be understood through implementation of the present disclosure. The objectives and other advantages of the present disclosure will be achieved through the structure specifically pointed out in the description, claims, and the accompanying drawings.

### BRIEF DESCRIPTION OF THE DRAWINGS

The drawings are provided for further understanding of the present disclosure, and constitute one part of the description. They serve to explain the present disclosure in conjunction with the embodiments, rather than to limit the present disclosure in any manner. In the drawings:

FIG. 1 schematically shows the structure of an existing array substrate row drive circuit detection device;

FIG. 2 schematically shows an output waveform of an existing array substrate row drive circuit;

FIG. 3 schematically shows the structure of a detection device for an array substrate row drive circuit according to Embodiment 1 of the present disclosure;

FIG. 4 schematically shows the structure of a detection module according to Embodiment 2 of the present disclosure;

FIG. 5 shows a waveform diagram of a superimposed signal corresponding to a normal row drive circuit, and a waveform diagram of a superimposed signal corresponding to an abnormal row drive circuit due to failure of an n^{th}-stage row drive unit according to Embodiment 2 of the present disclosure;

FIG. 6 schematically shows a flow chart of a detection method for an array substrate row drive circuit according to Embodiment 3 of the present disclosure; and

FIG. 7 schematically shows a flow chart of a procedure for determining an abnormally active row drive unit according to Embodiment 4 of the present disclosure.

### DETAILED DESCRIPTION OF THE EMBODIMENTS

The present disclosure will be explained in detail with reference to the embodiments and the accompanying drawings, whereby it can be fully understood how to solve the technical problem by the technical means according to the present disclosure and achieve the technical effects thereof, and thus the technical solution according to the present disclosure can be implemented. It is important to note that as long as there is no structural conflict, all the technical features mentioned in all the embodiments may be combined together in any manner, and the technical solutions obtained in this manner all fall within the scope of the present disclosure.

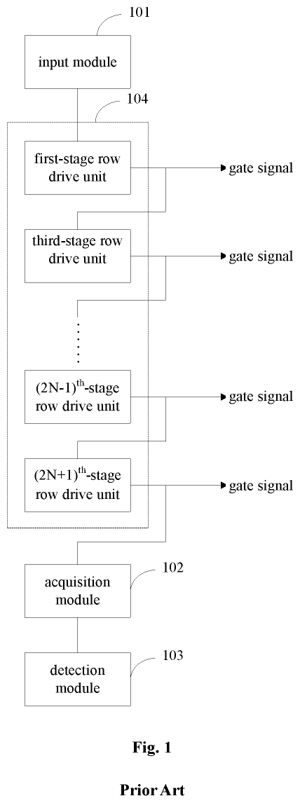

FIG. 1 schematically shows the structure of an existing array substrate row drive circuit detection device. As shown in FIG. 1, the existing array substrate row drive circuit detection device includes an input module 101, an acquisition module 102, and a detection module 103.

Specifically, the input module 101 inputs, to a first-stage row drive unit of an array substrate row drive circuit 104, a test signal for normally driving the row drive circuit 104, so as to enable the array substrate row drive circuit 104 to perform scanning normally. The acquisition module 102 acquires an output signal of a last-stage row drive unit of the array substrate row drive circuit 104. The detection module 103 judges whether or not the array substrate row drive circuit 104 has a drive failure in structure as a whole, by detecting whether or not a waveform of the output signal of the last-stage row drive unit of the array substrate row drive circuit 104 is normal.

In the existing array substrate row drive circuit 104, each stage row drive unit drives a corresponding gate line, and transmits a drive signal of a present stage row drive unit to a next stage row drive unit by means of a shift register. In general, a left array substrate row drive circuit 104 and a right side array substrate row drive circuit 104 are provided on two sides of a display area, respectively. That is, the row drive circuit 104 including odd-numbered rows of row drive units is provided on a left side of the display area, and the row drive circuit 104 including even-numbered rows of row drive units is provided on a right side of the display area. The left array substrate row drive circuit 104 and the right array substrate row drive circuit 104 alternately output driving signals under an interlaced drive mode.

The detection method of the row drive circuit 104 in the prior art will be described below with the left array substrate row drive circuit 104 as an example.

In particular, the input module 101 is connected to an input terminal of the first-stage row drive unit of the row drive circuit 104, for inputting a test signal to the first-stage row drive unit of the row drive circuit 104. In this case, the row drive circuit 104 includes a plurality of cascaded row drive units, i.e., the first-stage row drive unit, a third-stage row drive unit, a fifth-stage row drive unit, . . . , an n^{th}-stage row drive unit, a (2N−1)th-stage row drive unit, and a (2N+1)th-stage row drive unit, wherein n, an odd number in an interval [1, 2N+1], denotes a serial number of the row drive unit, and 2N+1 denotes a total number of row drive units of the row drive circuit 104.

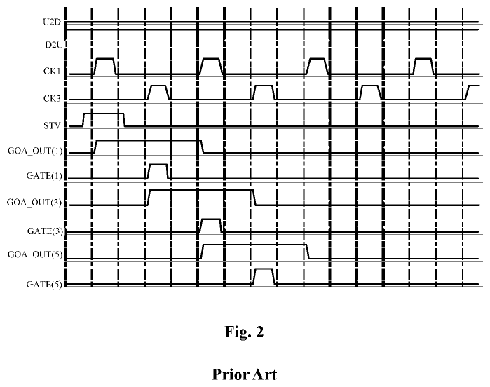

FIG. 2 schematically shows an output waveform of the existing array substrate row drive circuit 104. In FIG. 2, U2D and D2U respectively denote a forward scanning signal and a reverse scanning signal; CK1 and CK3 respectively denote a first clock signal and a third clock signal; STV denotes a frame start signal; GOA_OUT (1) represents the output signal of the first-stage row drive signal, and GATE (1) represents a first-row gate signal; GOA_OUT (3) represents the output signal of the third-stage row drive unit, and GATE (3) represents a third-row gate signal; and GOA_OUT (5) represents the output signal of the fifth-stage row drive unit, and GATE (5) represents a fifth-row of gate signal. When the left array substrate row drive circuit 104 is being detected, a waveform of the output signal of a last-stage row drive unit of the left array substrate row drive circuit 104 is mainly measured, to determine a working state of the left array substrate row drive circuit 104 based on a measurement result thereof. If the measurement result shows no output of a normal periodic square wave waveform (generally with a frequency of 60 Hz), the left array substrate row drive circuit 104 is then considered to fail as a whole.

The detection method of the right array substrate row drive circuit 104 is the same as the above-described detection method and will not be described herein.

It can be seen that the existing detection solution of the array substrate row drive circuit 104 generally only reflects abnormality of the array substrate row drive circuit 104 as a whole, but cannot determine a row drive unit which is specifically abnormal, thereby increasing the difficulty in parsing the abnormality.

In order to solve the above-mentioned technical problem, in embodiments of the present disclosure, a detection device and method for an array substrate row drive circuit are provided.

### Embodiment 1

In general, a left array substrate row drive circuit and a right array substrate row drive circuit are separately detected with a same detection method. Therefore, the following describes the case in which the left array substrate row drive circuit, as an example, is detected.

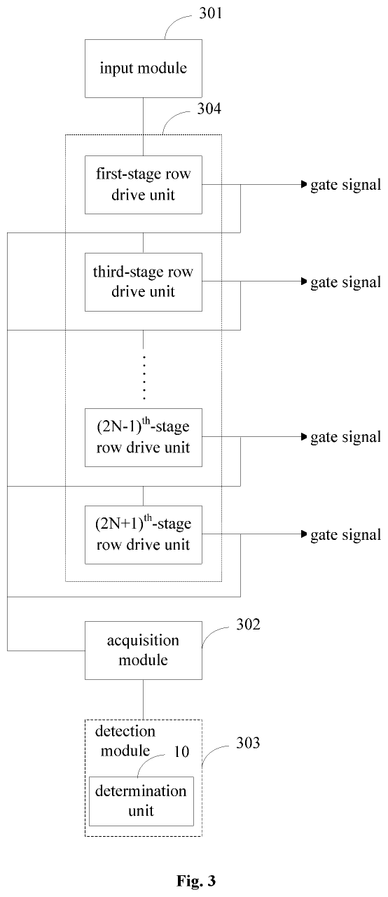

FIG. 3 schematically shows the structure of a detection device for an array substrate row drive circuit (herein a left array substrate row drive circuit, row drive circuit for short) according to Embodiment 1 of the present disclosure. As shown in FIG. 3, the detection device mainly includes an input module 301, an acquisition module 302, and a detection module 303.

Specifically, the input module 301 is connected to an input terminal of a first-stage row drive unit of a row drive circuit 304, for inputting a test signal to the first-stage row drive unit of the row drive circuit 304. In this case, the row drive circuit 304 includes a plurality of cascaded row drive units, i.e., the first-stage row drive unit, a third-stage row drive unit, a fifth-stage row drive unit, . . . , an nth-stage row drive unit, . . . , a (2N−1)^{th}-stage row drive unit, and a (2N+1)^{th}-stage row drive unit, wherein n, an odd number in an interval [1, 2N+1], denotes a serial number of the row drive unit, and 2N+1 denotes a total number of row drive units of the row drive circuit 104.

The acquisition module 302 is connected to output terminals of respective row drive units of the row drive circuit 304, for acquiring output signals of the respective row drive units.

The detection module 303 is connected to the acquisition module 302, for determining an abnormally active row drive unit based on the output signals of all the row drive units when it is determined that the row drive circuit 304 is operating abnormally.

A detection principle of the detection device for the array substrate row drive circuit 304 of the present embodiment will be described in detail below. To start with, the input module 301 inputs, to the first-stage row drive unit of the row drive circuit 304, a test signal for normally driving the row drive circuit 304, so as to enable the row drive circuit 304 to perform scanning normally. Herein, the test signal is a frame start signal. The acquisition module 302 acquires the output signals of the row drive units in the row drive circuit 304. The detection module 303, after determining that the row drive circuit 304 is operating abnormally, determines the row drive unit which is abnormally active in the row drive circuit 304, based on the output signals of all the cascaded row drive units in the row drive circuit 304.

In one preferred embodiment, the detection module 303 may further include a determination unit 10, for determining an operating state of the row drive circuit 304 based on the output signal of the last-stage row drive unit in the row drive circuit 304. Herein, the operating state of the row drive circuit 304 refers to the operating state of the row drive circuit 304 as a whole, which mainly reflects normal or abnormal operation of the row driving circuit 304 as a whole. In other words, the row drive circuit 304 includes two states, i.e., a normally operating state and an abnormally operating state.

The detection device and method for the right array substrate row drive circuit 304 (not shown in the drawing) are respectively the same as the detection device and method for the left array substrate row drive circuit 304, and will not be described herein.

With the detection device for the array substrate row drive circuit 304 of the present embodiment, the abnormally active row drive unit can be determined based on the acquired output signals of all the row drive units when the row drive circuit 304 is in abnormal operation. As compared with an existing solution in which it is possible to reflect the operating state of the row drive circuit 304 as a whole only in accordance with the acquired output signal of the last-stage row drive unit, in the solution of the present embodiment, with the knowledge of abnormality of the row drive circuit 304 as a whole, the position of the abnormally active row drive unit can be further determined, thereby improving the efficiency in detecting and parsing the abnormally active row drive unit. It can be seen that in the present embodiment, a more specific detection result can be obtained, thereby facilitating subsequent repair of the row drive circuit 304, and remarkably shortening the time for defect investigation in and elimination from the row drive circuit 304.

As described above, the detection device for the array substrate row drive circuit 304 of the present embodiment can provide practical guidance in the field of detection technologies of display panels.

### Embodiment 2

In the present embodiment, the structure of the detection module 303 in Embodiment 1 is further optimized.

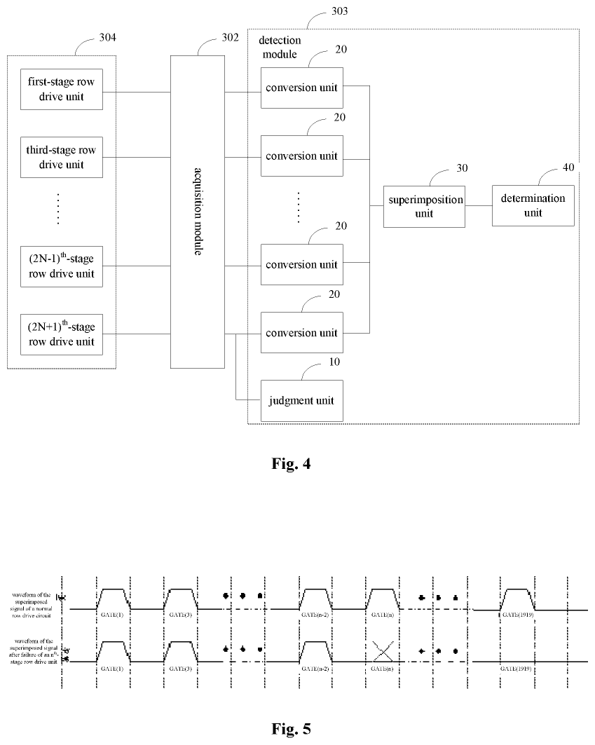

FIG. 4 schematically shows the structure of the detection module 303 according to Embodiment 2 of the present disclosure. As shown in FIG. 4, the detection module 303 of the present embodiment may include a superimposition unit 30, a determination unit 40, and a plurality of conversion units 20, wherein each conversion unit 20 is connected to an acquisition module 302. In addition, each of the conversion units 20 corresponds to a stage of row drive unit, for converting an output signal of the stage of row drive unit acquired by the acquisition module 302 into a pulse signal, and preventing the pulse signal from overlapping the pulse signal corresponding to any other row drive unit. The superimposition unit 30 is connected to the respective conversion units 20, respectively, for superimposing the pulse signals output from all the conversion units 20, to obtain a superimposed signal. The determination unit 40 is connected to the superimposition unit 30, for determining an abnormally active row drive unit based on the superimposed signal obtained by the superimposition unit 30.

The detection device of the present embodiment may further include a display module (not shown), for displaying a waveform of the superimposed signal, for easy examination by an operator. Herein, the display module can visually present the waveform of the superimposed signal to the operator, so as to facilitate the operator to be quickly and intuitively aware of the abnormal row drive unit.

The approach of screening the abnormally active row drive unit by the detection module 303 of the present embodiment will be described in detail below.

As shown in FIG. 4, each conversion unit 20 obtains the output signal of a corresponding row drive unit through the acquisition module 302. Specifically, in a first scanning period, the conversion unit 20 corresponding to a first-stage row drive unit is used for converting the output signal of the first-stage row drive unit into one pulse signal. In a third scanning period, the conversion unit 20 corresponding to a third-stage row drive unit is used for converting the output signal of the third-stage row drive unit into one pulse signal. It can be assumed that there is a total of 1920 stages of row drive units. The rest may be deduced by analogy, such that the conversion unit 20 corresponding to a 1919^{th}-stage row drive unit is used to convert the output signal of the 1919^{th}-stage row drive unit into one pulse signal. Therefore, regarding the row drive circuit 304 of the present embodiment, a total of 960 pulse signals are obtained. Moreover, it is important to note that the 960 pulse signals do not overlap each other. The superimposition unit 30 superimposes the 960 mutually non-overlapping pulse signals to obtain one superimposed signal. The determination unit 40 determines an abnormally active row drive unit based on the obtained superimposed signal.

In one preferred embodiment, each conversion unit 20 includes an NAND circuit, which is used to perform an NAND operation on a clock signal and the output signal of the row drive unit corresponding to the conversion unit 20, to obtain a pulse signal. Herein, the clock signal and the output signal both correspond to a specific conversion unit 20. In this way, through the NAND operation, it is possible to ensure that the pulse signals output from the respective conversion units 20 do not overlap each other, thus to ensure that the pulse signals output from the respective conversion units 20 do not overlap each other.

A principle of obtaining the non-overlapping pulse signals by the NAND circuit in the present embodiment is that, since clock signals of the row drive units in the row drive circuit 304 of the present embodiment do not overlap each other, the pulse signals obtained through the NAND operation between the output signals of respective stages of row drive units and the corresponding clock signals do not overlap each other.

In one preferred embodiment, the determination unit 40 is specifically used for determining a missing waveform in the superimposed signal and for determining the row drive unit corresponding to the missing waveform as the abnormally active row drive unit. The operation principle of the determination unit 40 will be described in detail with reference to FIG. 5.

FIG. 5 shows a waveform diagram of a superimposed signal corresponding to a normal row drive circuit 304, and a waveform diagram of a superimposed signal corresponding to an abnormal row drive circuit due to failure of an nth-stage row drive unit according to Embodiment 2 of the present disclosure. When the n^{th}-stage row drive unit is operating abnormally, the n^{th}-stage row drive unit fails to output a corresponding output signal. Since the row drive units are cascaded with each other, i.e., the output signal of an upper-stage row drive unit is used as an operation trigger signal of a next-stage row drive unit, none of the row drive units after the n^{th}-stage (the (n+2)^{th}-stage row drive unit to the 1910-stage row drive unit) can output a corresponding output signal, leading to loss of waveforms corresponding to the n^{th}-stage row drive unit to the 1919^{th}-stage row drive unit. As shown in FIG. 5, the waveform corresponding to the nth-stage row drive unit is missing, and the waveform corresponding to the (n+2)^{th}-stage row drive unit is missing. Subsequently, the waveforms corresponding to the (n+4)^{th}-stage row drive unit to the 1910-stage row drive unit are all missing. Since the pulse signals do not overlap each other, the missing waveform and its corresponding row drive unit can be visually determined from the superimposed signal. In this way, the determination unit 40 may determine the abnormally active row drive unit based on the missing waveform in the superimposed signal. Reference can be made to FIG. 5. Since the waveforms corresponding to the nth-stage row drive unit to the 1999^{th}-stage row drive unit are missing in the superimposed signal, it can be determined that the superimposed signal begins to be missing from the n^{th}-stage row drive unit. It can thus be derived that the n^{th}-stage row drive unit is in abnormal operation.

With the detection module 303 of the present embodiment, the characteristics of the clock signals and the NAND circuit can be skillfully used to convert the output signals of the respective stages of row drive units into non-overlapping pulse signals, and then to determine the abnormally active row drive unit based on the missing waveform in the superimposed signal obtained by superimposition of the respective pulse signals. It can be seen that the detection module 303 of the present embodiment is simple in structure and provides intuitive and accurate data support for accurate and effective determination of the abnormally active row drive unit.

### Embodiment 3

In an embodiment of the present disclosure, there is also provided a detection method for an array substrate row drive circuit 304 based on the same inventive concept. Similarly, the present embodiment will be described with a left array substrate row drive circuit 304 as an example.

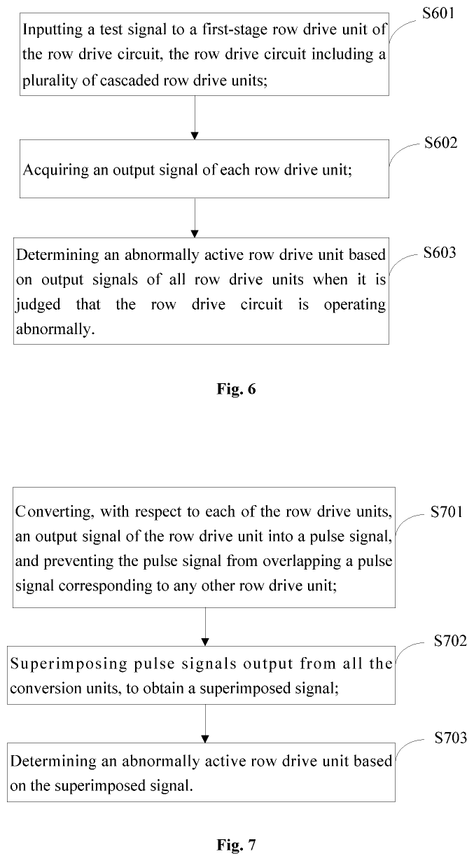

FIG. 6 schematically shows a flow chart of the detection method for the array substrate row drive circuit 304 according to Embodiment 3 of the present disclosure. As shown in FIG. 6, the detection method may include the following steps: step S610, step S620, and step S630.

In step S610, a test signal is input to a first-stage row drive unit of the row drive circuit 304. Herein, the row drive circuit 304 includes a plurality of cascaded row drive units.

In step S620, output signals of respective row drive units are acquired.

In step S630, when it is judged that the row drive circuit 304 is operating abnormally, a row drive unit which is abnormally active is determined based on the output signals of all the row drive units.

In one preferred embodiment, step S630 also includes determining an operating state of the row drive circuit 304 based on the output signal of a last-stage row drive unit.

With the detection method for the array substrate row drive circuit 304 of the present embodiment, the abnormally active row drive unit can be determined based on the acquired output signals of all the row drive units when the row drive circuit 304 is in abnormal operation. As compared with an existing solution in which it is possible to reflect the operating state of the row drive circuit 304 as a whole only in accordance with the acquired output signal of the last-stage row drive unit, in the solution of the present embodiment, with the knowledge of abnormality of the row drive circuit 304 as a whole, the position of the abnormally active row drive unit can be further determined, thereby improving the efficiency in detecting and parsing the abnormally active row drive unit. It can be seen that in the present embodiment, a more specific detection result can be obtained, thereby facilitating subsequent repair of the row drive circuit 304, and remarkably shortening the time for defect investigation in and elimination from the row drive circuit 304.

### Embodiment 4

In the present embodiment, the step S630 in the Embodiment 3 is further optimized.

FIG. 7 schematically shows a flow chart of a procedure for determining an abnormally active row drive unit according to Embodiment 4 of the present disclosure. The procedure is used to determine the abnormally active row drive unit based on output signals of all row drive units. As shown in FIG. 7, the procedure may include the following steps: step S710, step S720 and step S730.

In step S710, with respect to each row drive unit, the output signal of the row drive unit is converted into a pulse signal, which does not overlap the pulse signal corresponding to any other row drive unit.

Specifically, step S710 includes: performing, with respect to each row drive unit, an NAND operation on a clock signal and the output signal corresponding to the row drive unit, to obtain the pulse signal.

In step S720, the pulse signals corresponding to all the row drive units are superimposed to obtain a superimposed signal.

In step S730, an abnormally active row drive unit is determined based on the superimposed signal.

Specifically, step S730 includes determining a missing waveform in the superimposed signal, and determining a row drive unit corresponding to the missing waveform as the abnormally active row drive unit.

In one preferred embodiment, step S730 further includes displaying a waveform of the superimposed signal for easy examination by an operator. Here in the present embodiment, the waveform of the superimposed signal can be visually displayed to the operator, to facilitate the operator to be quickly and intuitively aware of the abnormally active row drive unit.

With the procedure for determining the abnormally active row drive unit according to the present embodiment, the characteristics of the clock signals and the NAND circuit can be skillfully used to convert the output signals of the respective stages of row drive units into non-overlapping pulse signals, and then to determine the abnormally active row drive unit based on the missing waveform in the superimposed signal obtained by superimposition of the respective pulse signals. It can be seen that the procedure of the present embodiment is simple and provides intuitive and accurate data support for accurate and effective determination of the abnormally active row drive unit.

For details of each of the above steps, reference may be made to the above description of the detection device of the present disclosure taken in conjunction with FIGS. 1 to 5, and they will not be described herein.

It will be understood by those skilled in the art that the above-described modules or steps of the present disclosure may be implemented by a general computing device. They may be concentrated on a single computing device or distributed over a network of a plurality of computing devices. Optionally, they may be implemented by a program code executable by the computing device, so as to be stored in a storage device and executed by the computing device, or may be separately made into individual integrated circuit modules, or multiple modules or steps thereof can be achieved by being made into a single integrated circuit module. Thus, the present disclosure is not limited to any particular combination of hardware and software.

The above description should not be construed as limitations of the present disclosure, but merely as exemplifications of preferred embodiments thereof. Any variations or replacements that can be readily envisioned by those skilled in the art are intended to be within the scope of the present disclosure.

1. A detection device for an array substrate row drive circuit, comprising:
an input module for inputting a test signal to a first-stage row drive unit of the row drive circuit, the row drive circuit including a plurality of cascaded row drive units;
an acquisition module for acquiring an output signal of each row drive unit; and
a detection module for determining an abnormally active row drive unit based on output signals of all row drive units when it is judged that the row drive circuit is operating abnormally.

2. The detection device according to claim 1, wherein the detection module comprises:
a plurality of conversion units, wherein each of the conversion units corresponds to a stage of row drive unit for converting an output signal of the stage of row drive unit into a pulse signal and preventing the pulse signal from overlapping a pulse signal corresponding to any other row drive unit;
a superimposition unit for superimposing pulse signals output from all the conversion units, to obtain a superimposed signal; and
a determination unit for determining an abnormally active row drive unit based on the superimposed signal.

3. The detection device according to claim 2, wherein the conversion unit includes an NAND circuit, for performing an NAND operation on a clock signal and the output signal of a row drive unit corresponding to the conversion unit, to obtain the pulse signal.

4. The detection device according to claim 2, wherein the determination unit is specifically used for determining a missing waveform in the superimposed signal and determining a row drive unit corresponding to the missing waveform as the abnormally active row drive unit.

5. The detection device according to claim 3, wherein the determination unit is specifically used for determining a missing waveform in the superimposed signal and determining a row drive unit corresponding to the missing waveform as the abnormally active row drive unit.

6. The detection device according to claim 2, further comprising a display module for displaying a waveform of the superimposed signal.

7. The detection device according to claim 3, further comprising a display module for displaying a waveform of the superimposed signal.

8. The detection device according to claim 4, further comprising a display module for displaying a waveform of the superimposed signal.

9. The detection device according to claim 5, further comprising a display module for displaying a waveform of the superimposed signal.

10. The detection device according to claim 2, wherein the detection module further comprises:
a judgment unit for determining, based on an output signal of a last-stage row drive unit, an operating state of the row drive circuit.

11. The detection device according to claim 3, wherein the detection module further comprises:
a judgment unit for determining, based on an output signal of a last-stage row drive unit, an operating state of the row drive circuit.

12. The detection device according to claim 4, wherein the detection module further comprises:
a judgment unit for determining, based on an output signal of a last-stage row drive unit, an operating state of the row drive circuit.

13. The detection device according to claim 5, wherein the detection module further comprises:
a judgment unit for determining, based on an output signal of a last-stage row drive unit, an operating state of the row drive circuit.

14. The detection device according to claim 6, wherein the detection module further comprises:
a judgment unit for determining, based on an output signal of a last-stage row drive unit, an operating state of the row drive circuit.

15. The detection device according to claim 7, wherein the detection module further comprises:
a judgment unit for determining, based on an output signal of a last-stage row drive unit, an operating state of the row drive circuit.

16. A detection method for an array substrate row drive circuit, comprising the steps of:
inputting a test signal to a first-stage row drive unit of the row drive circuit, the row drive circuit including a plurality of cascaded row drive units;
acquiring an output signal of each row drive unit; and
determining an abnormally active row drive unit based on output signals of all row drive units when it is judged that the row drive circuit is operating abnormally.

17. The detection method according to claim 16, wherein the step of determining an abnormally active row drive unit based on the output signals of all the row drive units comprises:
converting, with respect to each of the row drive units, an output signal of the row drive unit into a pulse signal, and preventing the pulse signal from overlapping a pulse signal corresponding to any other row drive unit;
superimposing pulse signals output from all the conversion units, to obtain a superimposed signal; and
determining an abnormally active row drive unit based on the superimposed signal.

18. The detection method according to claim 17, wherein converting, with respect to each of the row drive units, an output signal of the row drive unit into a pulse signal, and preventing the pulse signal from overlapping a pulse signal corresponding to any other row drive unit comprises:
performing, with respect to each of the row drive units, an NAND operation on a clock signal and the output signal corresponding to the row drive unit, to obtain the pulse signal.

19. The detection method according to claim 17, wherein determining an abnormally active row drive unit based on the superimposed signal comprises:
determining a missing waveform in the superimposed signal, and determining a row drive unit corresponding to the missing waveform as the abnormally active row drive unit.

20. The detection method according to claim 18, wherein determining an abnormally active row drive unit based on the superimposed signal comprises:
determining a missing waveform in the superimposed signal, and determining a row drive unit corresponding to the missing waveform as the abnormally active row drive unit.
